(19) United States
(12) Patent Application Publication
(10) Pub. No.: US 2013/0187247 A1
(43) Pub. Date: Jul. 25, 2013

(54) MULTI-BIT MAGNETIC TUNNEL JUNCTION MEMORY AND METHOD OF FORMING SAME

(71) Applicants: Wenqing WU, San Diego, CA (US); Sean Li, San Diego, CA (US); Xiaochun Zhu, San Diego, CA (US); Raghu Sagar Madala, San Diego, CA (US); Seung H. Kang, San Diego, CA (US); Kendrick H. Yuen, San Diego, CA (US)

(72) Inventors: Wenqing WU, San Diego, CA (US); Sean Li, San Diego, CA (US); Xiaochun Zhu, San Diego, CA (US); Raghu Sagar Madala, San Diego, CA (US); Seung H. Kang, San Diego, CA (US); Kendrick H. Yuen, San Diego, CA (US)

(73) Assignee: QUALCOMM Incorporated, San Diego, CA (US)

(21) Appl. No.: 13/356,530

(22) Filed: Jan. 23, 2012

(51) Int. Cl. H01L 29/82; H01L 21/8246

(52) U.S. Cl. 257/421; 438/3; 257/E29.323; 257/E21.665

(57) ABSTRACT

A spin-torque transfer (STT) magnetic tunnel junction (MTJ) memory includes a unitary fixed magnetic layer, a magnetic barrier layer on the unitary fixed magnetic layer, a free magnetic layer having a plurality of free magnetic islands on the magnetic barrier layer, and a cap layer overlying the free magnetic layer. Also a method of forming an STT-MTJ memory.

### FIELD OF THE INVENTION

The present invention is directed toward a multi-bit magnetic tunnel junction memory and toward a method of forming same, and, more specifically, toward a multi-bit magnetic tunnel junction memory having a plurality of free magnetic elements associated with a unitary fixed magnetic layer and toward a method of forming same.

### BACKGROUND

A spin-torque transfer (STT) magnetic tunnel junction (MTJ) element comprises a fixed magnetic layer, the magnetic state of which is fixed, and a free magnetic layer, the magnetic state of which is selectively reversible, The fixed and free layers are separated by a magnetic barrier or junction layer. The STT-MTI element is switchable between two mutually opposite, stable magnetization states—“parallel” (P) and “anti-parallel” (AP), by passing an electric write current through its layers. If the write current is above a given critical point the STT-MTJ will switch into the P or AP state induced by the direction of the write current. A conventional STT-MTJ memory cell stores one bit, with one of the P and AP states assigned to represent a first binary value, e.g., a “0”, and the other assigned to represent a second binary value, e.g., a “1.” The stored binary value can be read because STT-MTJ elements have a lower electrical resistance in the P state than the AP state.

Conventional STT-MTJ memory employs write circuitry designed to inject a write current having a magnitude high enough and duration long enough to ensure it switches the STT-MTJ element to the desired P/AP state. Conventional design philosophy for STT-MTI memory is therefore a “deterministic” writing confined to the design paradigm of conventional memories, such as SRAM, where the switching of memory elements is deterministic.

It is also known to provide a cluster of STT-MTJ cells to form a memory element that can take on one of a plurality of different states depending on how many of the STT--MTJ cells are in a parallel states and how many of the STT-MTJ cells are in an anti-parallel state. A cluster having N STT-MTJ cells can take on any one of 2ⁿ different states and thus present one of 2ⁿ different resistances to a measurement circuit,

Such a measurement only requires access to the input and output of the overall STT-MTJ cluster and does not require access to or knowledge of the states of any of the individual STT-MTJ cells.

FIG. 1 shows a circuit 100 that includes an N-element STT-MTJ cluster cell 102 comprising N STT-MTJ elements 102-1, 102-2 . . . 102-N connected in series. The N-element STT-MTJ cluster cell 102 is coupled at one end 102A to a read/write current (BL) line 104 and coupled at its other end 102B through an enabling switch 106 to another read/write current (SL) line 108. FIG. 1 also includes an N-element STT-MTJ cluster cell 150 comprising N STT-MTJ elements 152-1,152-2 . . . 152-N connected in parallel and connected to the SL line 108 via an enabling switch 154. It will be understood that the BL line 104 and the SL line 108 may extend and couple to each of a plurality of additional STT-MTJ clusters (not shown). The BL line 104 and the SL line 108 may be in accordance with conventional n×m array STT-MTJ memory bit line and source line. Likewise the enabling switch 106 may be in accordance with a conventional n×m array STT-MTJ memory word enable switch. It will also be understood that the BL line 104, the SL line 108, and the enabling switch may be other than convention bit lines, source lines and word transistors, respectively.

A probabilistic programming current (PGC) source 110 controlled by a probabilistic programming (PPG) controller unit 112 couples to the BL line 104 and to the SL line 108. An N+1 level voltage detector 114 may have a sense input 114A coupled to the BL line 104 though a read enabling switch 116, and a sense input 114B coupled to an M-bit to Nil level converter 118. The M-bit data to N+1 level converter 118 may convert the M-bit data into an N+1 level target resistance voltage signal. The N+1 level converter 118 may provide a. compare signal to the PPG controller 112. It will be understood that the N+1 level voltage detector 114 may include a read current source (not explicitly shown) to inject a read current via the BL line 104 through the N-element STT-MTJ cluster cell 102.

In operation, the PPG controller 112 causes the PGC current source 110 to apply a current to the SL line 108 and the enabling switch 106 is activated to apply this current to the N-element STT-MTJ cluster cell 102. The current level and duration are selected such that, with each current application, there is a. predetermined chance of switching the state of one of the N STT-MTJ elements 102-1 through 102-N from a first state to a second state, based on the direction of the current. After a current is applied, the N+1 level voltage detector 114 measures the resistance of the N-element STT-MTJ cluster cell 102 to determine how many of the STT-MTJ cells are in the desired state, and current is applied in a required direction until the desired resistance level of the N-element STT-MTJ cluster cell 102 is obtained. In this manner, the N-element STT-MTI cluster cell 102 can represent 2ⁿ bits of information. The N-element STT-MTJ cluster cell 150 may be controlled and used to store multiple bits of data in a similar manner.

STT-MTJ cell clusters as discussed above are useful to provide multi-bit storage in a given area h is desirable to increase the density of STT-MTJ elements in an STT-MTJ cluster while maintaining the aforementioned functionalities.

### SUMMARY

An exemplary embodiment includes a spin-torque transfer (STT) magnetic tunnel junction (MTJ) memory having a first unitary fixed magnetic layer, a first magnetic barrier layer on the first unitary fixed magnetic layer, a first free magnetic layer comprising a first plurality of free magnetic islands on the first magnetic barrier layer, and a cap layer overlying the first free magnetic layer.

Another embodiment comprises a method of forming an STT-MTJ memory that includes providing a first unitary fixed magnetic layer, forming a first magnetic barrier layer on the first unitary fixed magnetic layer, forming a first free magnetic layer, comprising a plurality of free magnetic islands, on the first magnetic barrier layer, and providing a cap layer overlying the first free magnetic layer.

A further embodiment includes an STT-MTJ memory that include a first unitary fixed magnetic layer, a first magnetic barrier layer arrangement on the first unitary fixed magnetic layer, a first free magnetic layer arrangement comprising a first plurality of free magnetic islands on the first magnetic barrier layer arrangement and a cap layer arrangement overlying the first free magnetic layer arrangement.

Another embodiment comprises a method of forming an STT-MTJ memory that includes a step for providing a first unitary fixed magnetic layer, a step for forming a first magnetic barrier layer on the first unitary fixed magnetic layer, a step for forming a first free magnetic layer, comprising a plurality of free magnetic islands, on the first magnetic barrier layer, and a step for providing a cap layer overlying the first free magnetic layer.

### BRIEF DESCRIPTION OF THE DRAWINGS

The accompanying drawings are presented to aid in the description of embodiments of the invention and are provided solely for illustration of the embodiments and not limitation thereof.

FIG. 1 is a circuit diagram illustrating first and second conventional STT-MTJ cluster cell memory arrangements in a probabilistic programming circuit.

FIG. 2 is a schematic illustration of an STT-MTJ cluster cell memory according to a first embodiment.

FIG. 3 is a schematic illustration of an STT-MTJ cluster cell memory according to a second embodiment.

FIG. 4 is a schematic illustration of an STT-MTJ cluster cell memory according to a third embodiment.

FIG. 5 is a schematic illustration of an STT-MTJ cluster cell memory according to a fourth embodiment.

FIG. 6 is a schematic illustration of an STT-MTJ cluster cell memory according to a fifth embodiment,

FIG. 7 is a schematic illustration of an STT-MTI cluster cell memory according to a sixth embodiment

FIG. 8 is a flow chart illustrating a method according to an embodiment.

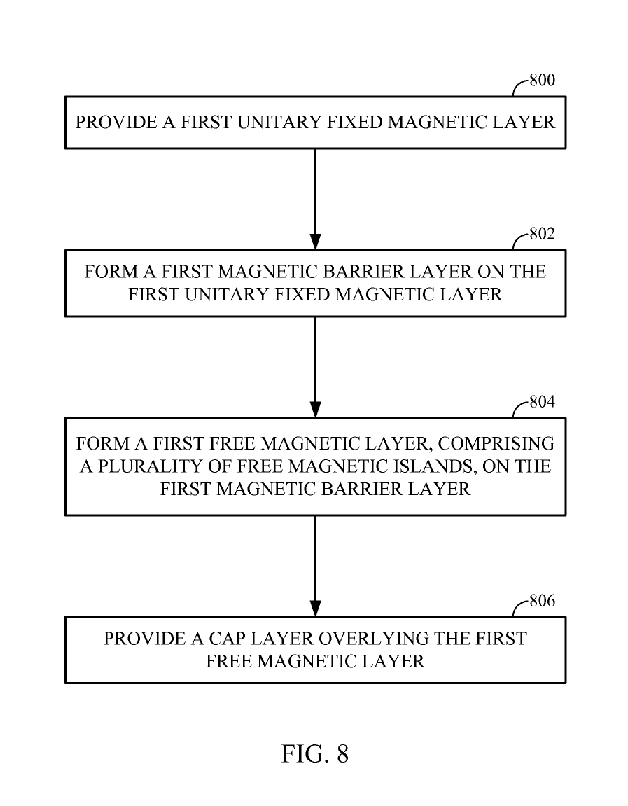

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example. “logic configured to” perform the described action.

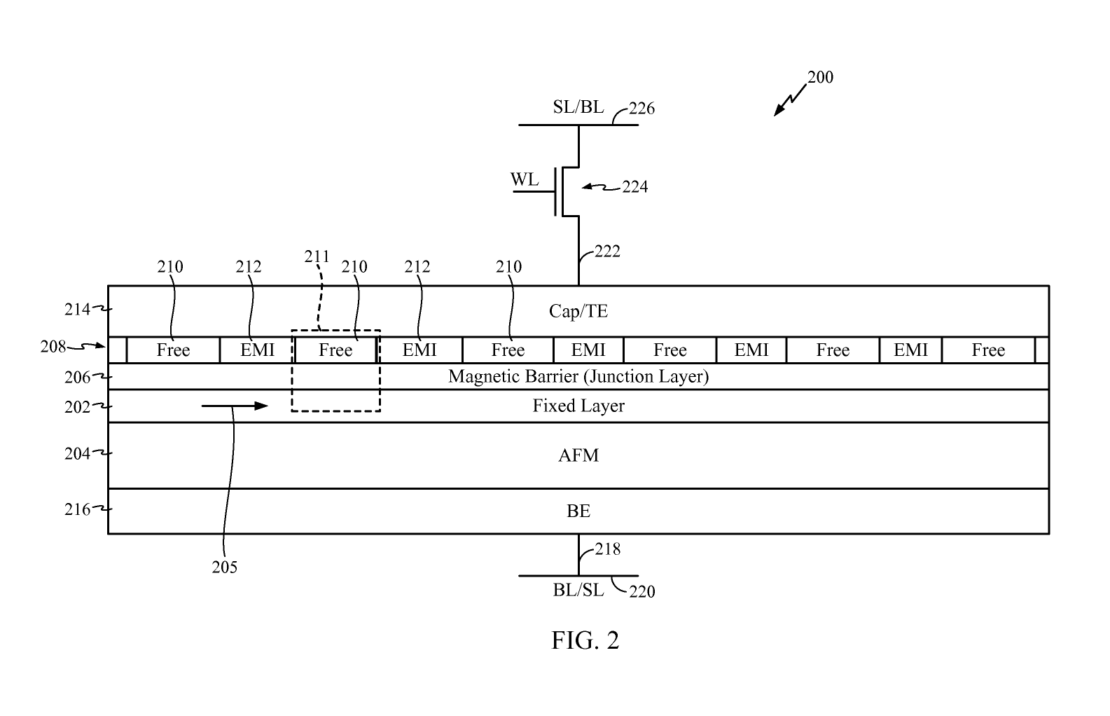

Referring now to FIG. 2, an STT-MTJ cluster cell memory 200 is illustrated that includes a first unitary fixed magnetic layer 202 formed of a unitary layer of magnetic material and a first anti-ferromagnetic layer 204 on which the first unitary fixed magnetic layer 202 is formed. As used herein, “unitary” means that a layer, such as the first unitary fixed magnetic layer 202, is substantially and/or topologically continuous and is configured to be shared by a plurality of individual free magnetic regions as discussed hereafter. The magnetic direction of the first unitary fixed magnetic layer 202 is fixed in a first direction indicated by an arrow 205 or to the right as viewed in FIG. 2.

A first magnetic barrier layer 206, sometimes referred to as a “junction layer,” comprising a unitary layer of material, is formed on the first unitary fixed magnetic layer 202, and a first free magnetic layer 208 is formed on the first magnetic barrier layer 206. The first free magnetic layer 208 comprises first plurality of individual free magnetic islands 210 each of which is in contact with the first magnetic barrier layer 206 but which are separated from one another by first regions 212 of electromagnetic insulating material, The first magnetic barrier layer 206 is substantially homogenous, and its properties are substantially similar in regions underlying the first free magnetic islands 210 and in regions beneath the first plurality of regions 212 of electromagnetic insulating material.

Each of the first plurality of free magnetic islands 210 has a footprint over the first unitary fixed magnetic layer 202 and forms, with the region of first magnetic barrier layer 206 between each of the first plurality of five magnetic islands 210 and the portion of the first unitary fixed magnetic layer 202 therebeneath, a magnetic tunnel junction 211, The general location of a single magnetic tunnel junction 211 is illustrated with a dashed outline in FIG. 2; each of the remaining ones of the first plurality of free magnetic islands 210 is part of a similar magnetic tunnel junction 211, The magnetic tunnel junctions 211 formed by these layers thus share a common fixed magnetic layer, namely, the first unitary fixed magnetic layer 202, and a common magnetic barrier layer, namely, the first magnetic barrier layer 206. A cap layer 214 is formed over the first free magnetic layer 208 in direct contact with the first plurality of free magnetic islands 210 and the first plurality of regions 212 of electromagnetic insulating material.

FIG. 2 illustrates six of the first plurality of free magnetic islands 210; however, it should be understood that the first plurality of free magnetic islands 210 in a given STT-MTJ cluster cell memory may comprise a greater or lesser number of free magnetic islands 210 without departing from the scope of the present disclosure. Moreover, while the first plurality of free magnetic islands 210 are illustrated as being arranged in a single straight line, such free magnetic islands 210 may cover the plane of the first magnetic barrier layer 206 and thus form an array or other pattern over the surface of the first magnetic barrier layer 206. It is generally desirable to make the individual free magnetic islands 210 as small and to space them as closely to one another as existing manufacturing conditions permit while maintaining an adequate spacing to substantially prevent the STT-MTJ's formed by the first plurality of free magnetic islands 210 from interfering with one another.

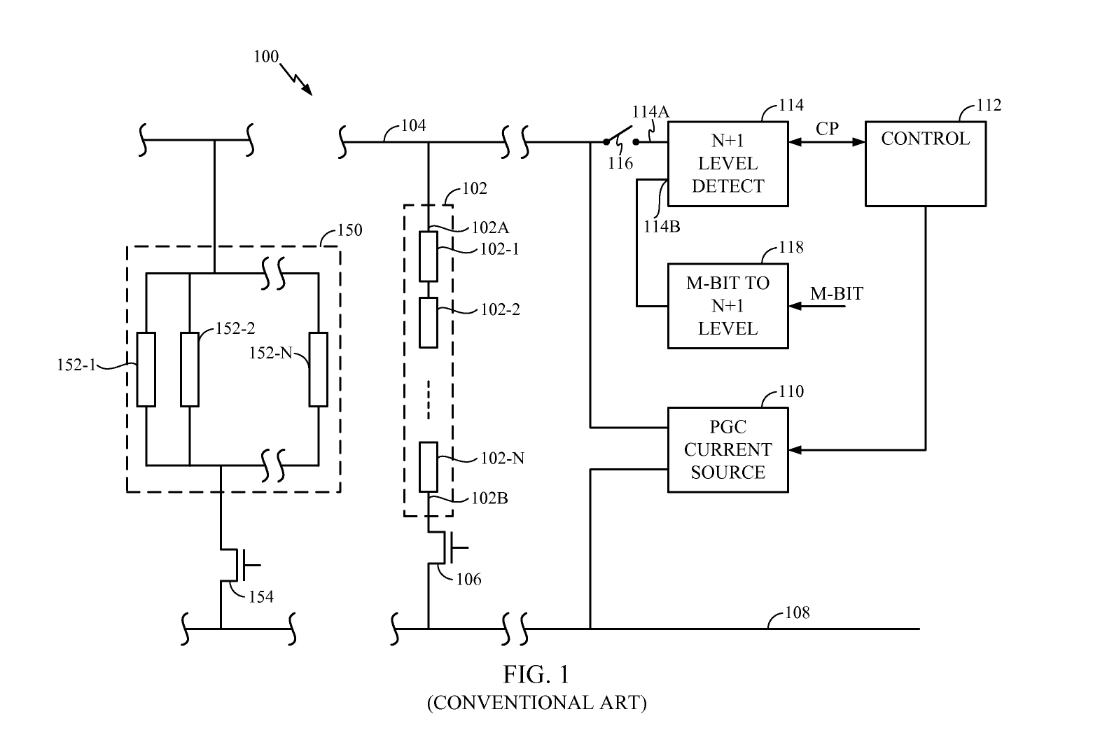

The aforementioned first anti-ferromagnetic layer 204 is mounted on a connection layer 216, which may be formed, for example, of tantalum, and a first line 218 is electrically connected to the connection layer 216 and to a bit line/source line 220. A second line 222 connects the cap layer 214 to a switch 224 which in turn is controllable to selectably connect the cap layer 214 to a source line/bit line 226. Like the connection layer 216, the cap layer 214 may be formed from tantalum, or, alternately, may include layers of tantalum and other materials such as ruthenium or magnesium oxide, or may be formed of tantalum nitride or titanium nitride. The bit line/source line 220 and the source line/bit line 226 are connected to a control circuit generally similar to the circuit illustrated in FIG. 1, and current applied between the cap layer 214 and the connection layer 216 probabilistically changes the state of one or more of the STT-MTJ's in the STT-MTJ cluster cell memory 200 in the manner described above.

The use of a common or shared fixed magnetic layer in association with multiple free magnetic islands 210 beneficially lowers the energy required for switching an STT-MTJ, and the energy required for switching all the magnetic tunnel junctions 211 formed by the first plurality of free magnetic islands 210 is less than that required for switching an STT-MTJ having a free layer with an area equal to the combined areas of all the first plurality of free magnetic islands 210. Using unitary layers of material, such as the first unitary fixed magnetic layer 202 and the first magnetic barrier layer 206 also provides an improved yield and increases tolerance for manufacturing defects in these layers. Furthermore, the large area of the first unitary fixed magnetic layer 202 makes this layer more magnetically stable than individual regions of fixed magnetic material in conventional STT-MTJ's, and the size of the first unitary fixed magnetic layer 202 also increases the tunnel magnetoresistance of the STT-MTJ's formed by this layer.

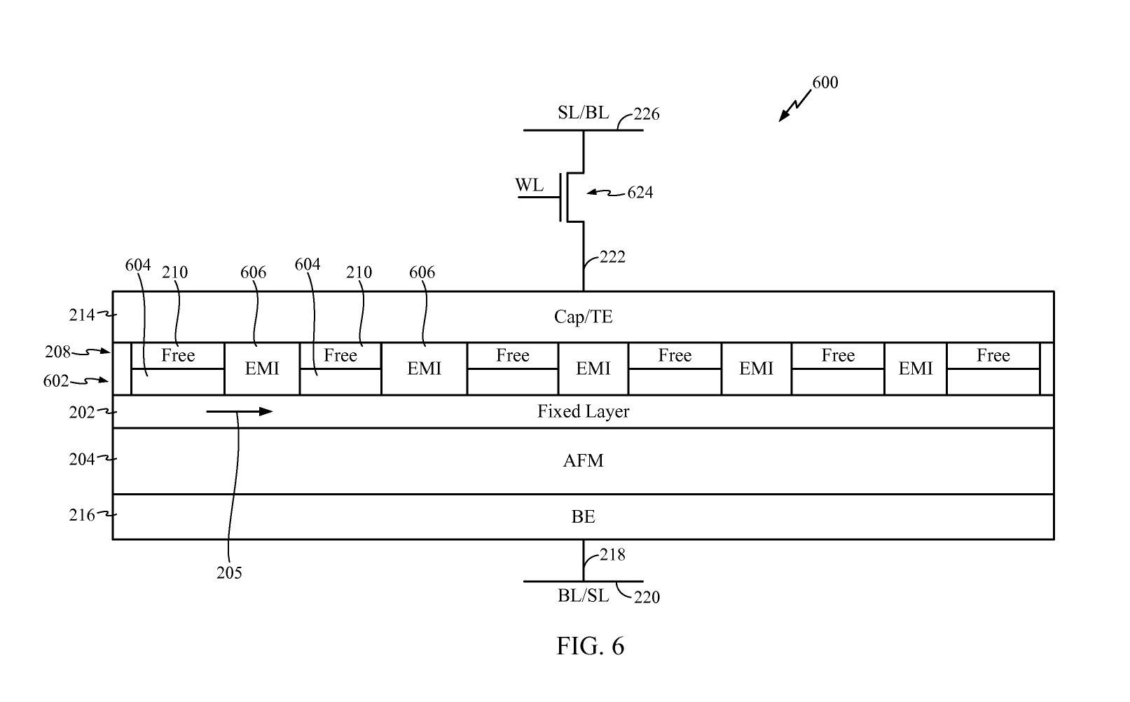

FIG. 6 illustrates an STT-MTJ cluster cell memory 600 that is similar to the STT-MTJ cluster cell 200 memory of FIG. 2 but in which a first magnetic barrier layer 602 comprises a plurality of individual barrier layer islands 604 beneath each of the first plurality of five magnetic islands 210 and in which regions 606 of electromagnetic insulating material extend from the cap layer 214 to the first unitary fixed magnetic layer 202. The cap layer 214 is connected to the source line/bit line 226 by a switch 624. The performance of the cluster cell 600 is comparable to that of the STT-MTJ cluster cell memory 200, but the STT-MTJ cluster cell memory 600 may be easier to manufacture than the STT-MTJ cluster cell memory 200 under certain manufacturing conditions.

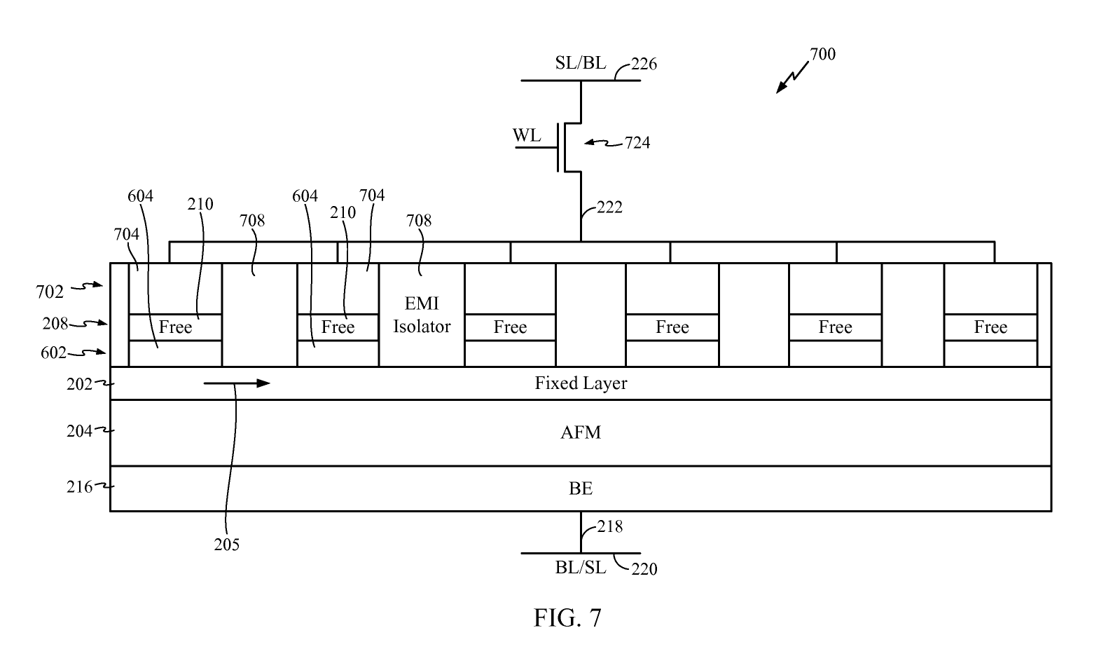

FIG. 7 illustrates an STT-MTJ memory or cluster cell 700 that is similar to the STT-MTJ cluster cell memory 600 of FIG. 6 and which includes a magnetic barrier layer 602 comprising a plurality of magnetic harrier islands 604. In addition, the STT-MTJ cluster cell 700 includes a cap layer 702 divided into a plurality of cap layer islands 704 each of which is connected to the source line/bit line 226 by a switch 724. Regions 708 of electromagnetic isolation material separate the adjacent cap layer islands 706, the adjacent free magnetic islands 210 and the adjacent magnetic barrier islands 604. The performance of this STT-MTJ cluster cell memory 700 may be similar to that of the STT-MTJ cluster cell memories 200 and 600 but, under some conditions, may be easier to manufacture.

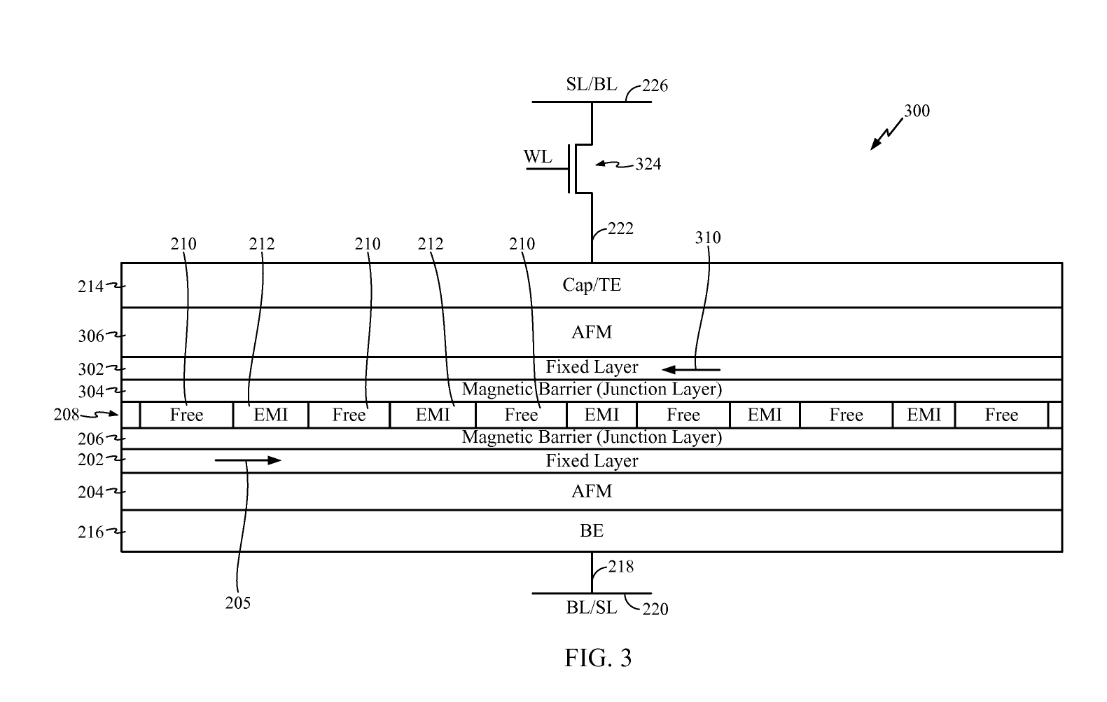

FIG. 3 illustrates an STT-MTJ cluster cell memory 300 according to another embodiment in Which elements common to the previous embodiments are identified using the same reference numerals. The STT-MTJ duster cell memory 300 includes a second fixed magnetic layer 302, comprising a unitary layer of material, spaced from the first free magnetic layer 208 by a second magnetic barrier layer 304, also comprising a unitary layer of material. A second anti-ferromagnetic layer 306 is present between the second fixed magnetic layer 302 and the cap layer 214 which helps maintain the magnetic orientation of the second fixed magnetic layer 302 in a direction opposite to that of the first unitary fixed magnetic layer 202 as indicated by an arrow 310, pointing to the left in FIG. 3. The cap layer 214 is connected to the source line/bit line 226 by a switch 324. The magnetic state of the plurality of free magnetic islands 210 is programmed probabilistically as described above, and the presence of the second fixed magnetic layer 302 and the second magnetic barrier layer 304 helps provide symmetric read/write characteristics for the first plurality of free magnetic islands 210. This arrangement also improves tunnel magnetoresistance due to the additional junction and also improves state density.

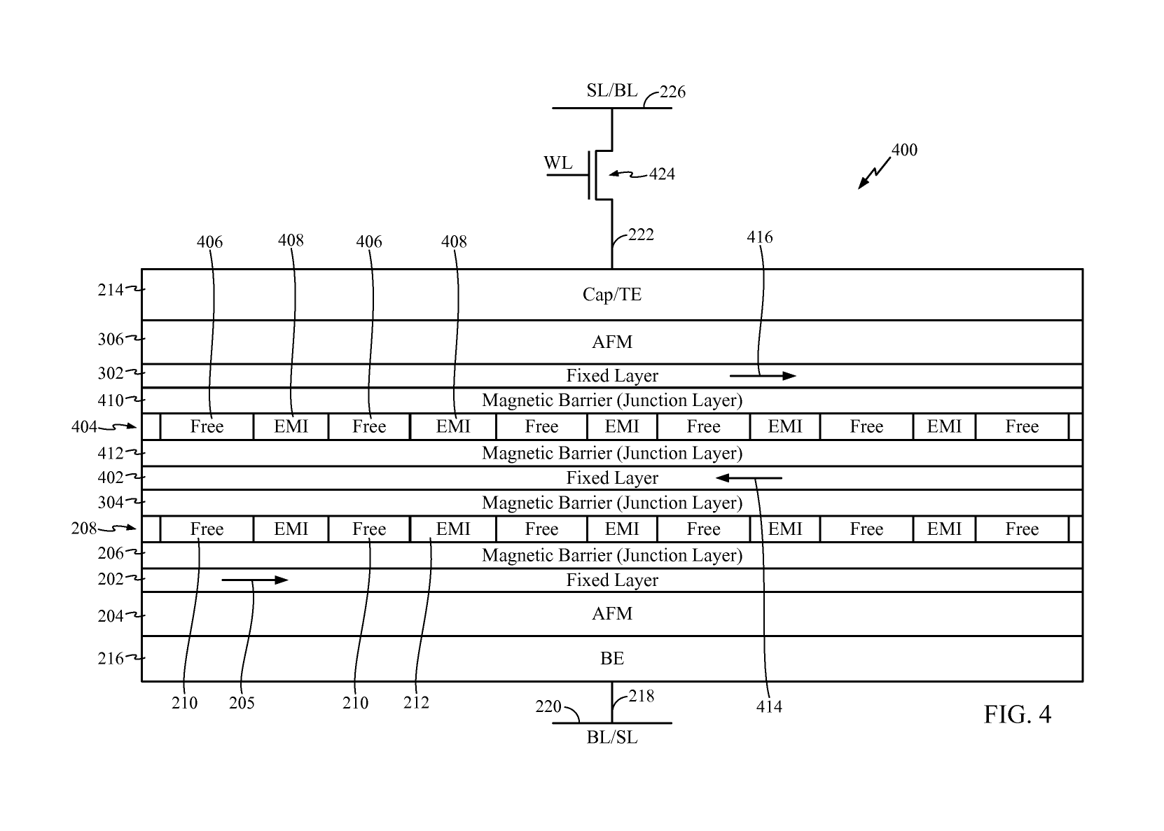

FIG. 4 illustrates an STT-MTJ cluster cell memory 400 according to another embodiment in which elements common to the previous embodiments are identified using the same reference numerals. In addition to the layers described above in connection with FIG. 3, the STT-MTJ cluster cell memory 400 includes a third fixed magnetic layer 402 between the second magnetic barrier layer 304 and the second fixed magnetic layer 302 and a second free magnetic layer 404 between the second fixed magnetic layer 302 and the third fixed magnetic layer 402. The second free magnetic layer 404 includes a second plurality of free magnetic islands 406 separated by second regions 408 of electromagnetic insulating material. A third magnetic barrier layer 410 extends between the second fixed magnetic layer 302 and the second free magnetic layer 404, and a fourth magnetic barrier layer 412 extends between the second free magnetic layer 404 and the third fixed magnetic layer 402. The directions of the fixed magnetic layers should alternate, and thus in this embodiment, the magnetization direction of the first unitary fixed magnetic layer 202 continues to face to the right in FIG. 4 as illustrated by arrow 205, the magnetization direction of the third fixed magnetic layer 402 faces in the opposite direction as shown by an arrow 414, and the magnetization direction of the second fixed magnetic layer 302 faces to the right, in the direction of an arrow 416. The cap layer 214 is connected to the source line/bit line 226 by a switch 424. This arrangement provides a second layer of sites having a reversible magnetic state and further improves the state density of the STT-MTJ cluster cell memory 100.

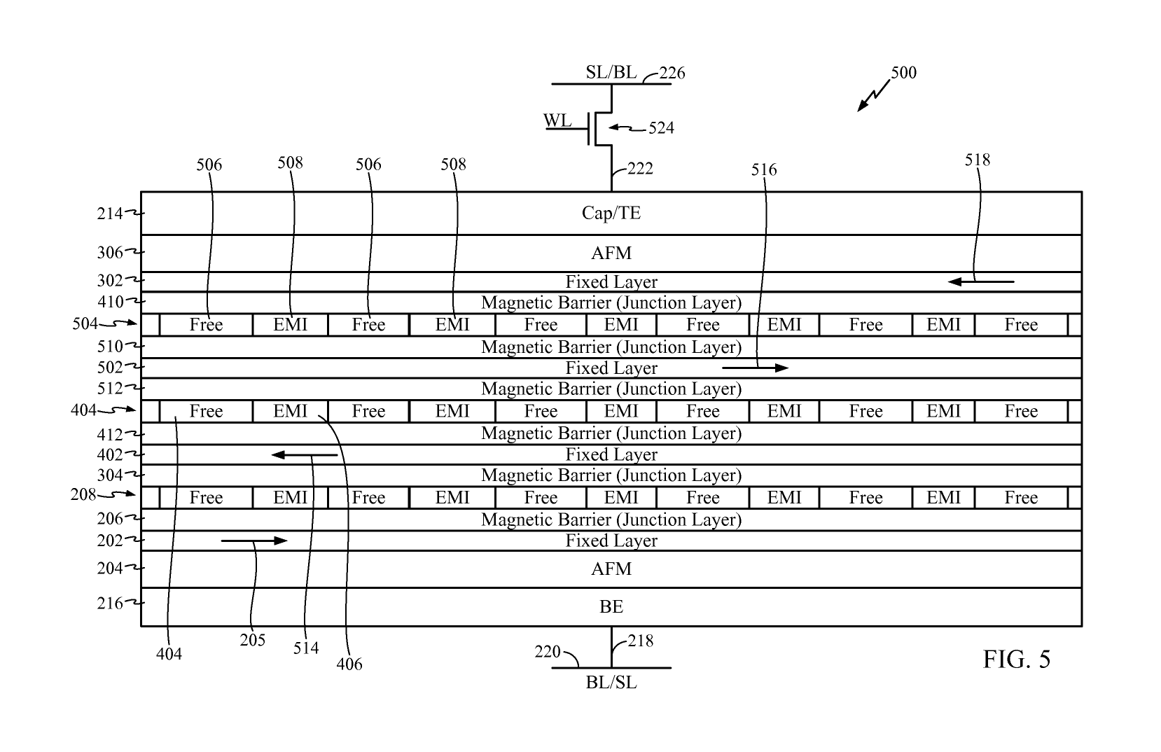

FIG. 5 illustrates another STT-MTJ cluster cell memory 500 according to another embodiment in which elements common to the previous embodiments are identified using the same reference numerals. The cluster cell 500 includes a fourth fixed magnetic layer 502 between the second free magnetic layer 404 and the third magnetic barrier layer 410 and a third free magnetic layer 504 comprising a third plurality of free magnetic islands 506 separated by a third plurality of regions 508 of electromagnetic insulating material. A fifth magnetic barrier layer 510 separates the fourth fixed magnetic layer 502 from the third free magnetic layer 504, and a sixth magnetic barrier layer 512 separates the fourth fixed magnetic layer 502 from the second free magnetic layer 404. The magnetization directions of the first through fourth magnetization layers 202, 302, 402 and 502 alternate, and the magnetization direction of the first magnetization layer 202 is illustrated by an arrow 205, to the right in FIG. 5, the magnetization direction of the third magnetization layer 302 is to the left in FIG. 5 as illustrated by an arrow 514, the magnetization direction of the fourth fixed magnetization layer 502 is to the right as illustrated by an arrow 516 and the magnetization direction of the second fixed magnetization layer 202 is to the left as illustrated by an arrow 518. The cap layer 214 is connected to the source line/bit line 226 by a switch 524. The arrangement of this embodiment further improves state density.

The STT-MTJ cluster cells of the foregoing embodiments are useful in various fields and devices and may, for example, be integrated into one or more semiconductor dies. The STT-MTJ cluster cells may also be used in various devices including, without limitation, a set top box, a music player, a video player, an entertainment unit, a navigation device, a communications device, a personal digital assistant (PDA), fixed location data unit, or a computer.

A method according to an embodiment includes a block 800 of providing a first unitary fixed magnetic layer, a block 802 of forming a first magnetic barrier layer on the first unitary fixed magnetic layer, a block 804 of forming a first free magnetic layer, comprising a plurality of free magnetic islands, on the first magnetic barrier layer, and a block 806 of providing a cap layer overlying the first free magnetic layer.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor,

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order, Furthermore, although elements of the invention may be described or claimed in the singular, the plural is contemplated unless limitation to the singular is explicitly stated.

What is claimed is:

1. A spin-torque transfer (STT) magnetic tunnel junction (MTV) memory comprising:
a first unitary fixed magnetic layer;
a first magnetic barrier layer on the first unitary fixed magnetic layer;
a first free magnetic layer comprising a first plurality of free magnetic islands on the first magnetic barrier layer; and
a cap layer overlying the first free magnetic layer.

2. The STT-MTJ memory of claim 1, wherein said cap layer is directly connected to said first plurality of free magnetic islands

3. The STT-MTJ memory of claim 1, wherein said cap layer comprises a plurality of individual cap layer islands associated with said first plurality of free magnetic islands of said first free magnetic layer.

4. The STT-MTJ memory of claim 1 wherein the first magnetic barrier layer is homogeneous.

5. The STT-MTJ memory of claim 1, wherein the first magnetic barrier layer comprises a first plurality of individual magnetic barrier islands, each one of said first plurality of individual magnetic barrier islands being associated with at least one of said first plurality of free magnetic islands.

6. The STT-MTJ memory of claim 1, wherein said first magnetic barrier layer comprises a first plurality of individual magnetic barrier islands separated by an electromagnetic isolator material and wherein each of the first plurality of free magnetic islands has a footprint over the first unitary fixed magnetic layer and wherein each one of said first plurality of individual magnetic barrier islands has substantially said footprint and is located between one of the first plurality of free magnetic islands and said first unitary fixed magnetic layer.

7. The STT-MTJ memory of claim 1, including a first anti-ferromagnetic layer adjacent said first unitary fixed magnetic layer on a side of the first unitary fixed magnetic layer opposite said first magnetic barrier layer.

8. The STT-MTJ memory of claim , including a connecting layer adjacent said first anti-ferromagnetic layer and electrically connected to a first line and the STT-MTJ memory including a second line electrically connected to said cap layer.

9. The STT-MTJ memory of claim 1, including a second unitary fixed magnetic layer between said cap layer and said first free magnetic layer and a second magnetic barrier layer between said second unitary fixed magnetic layer and said first free magnetic layer.

10. The STT-MTJ memory of claim 9, wherein said second magnetic barrier layer is connected to said first plurality of free magnetic islands on a side of said first plurality of free magnetic islands opposite from said first magnetic barrier layer.

11. The STT-MTJ memory of claim 9, including a second anti-ferromagnetic layer between said second unitary fixed magnetic layer and said cap layer.

12. The STT-MTJ memory of claim 9, including at least one additional unitary fixed magnetic layer between said second unitary fixed magnetic layer and said first unitary fixed magnetic layer and at least one additional free magnetic layer comprising at least one additional plurality of free magnetic islands.

13. The STT-MTJ memory of claim 9, including a second free magnetic layer comprising a second plurality of free magnetic islands between the second magnetic barrier layer and said first free magnetic layer.

14. The STT-MTJ of claim 13, including a third unitary fixed magnetic layer between said first free magnetic layer and said second free magnetic layer, a third magnetic barrier layer between said third unitary fixed magnetic layer and said second free magnetic layer and a fourth magnetic barrier layer between said third unitary fixed magnetic layer and said first free magnetic layer.

15. The STT-MTJ memory of claim 1 integrated into at least one semiconductor die.

16. The STT-MTJ memory of claim 1 integrated into a device selected from the group consisting of a set top box, a music player, a video player, an entertainment unit, a navigation device, a communications device, a personal digital assistant (PDA), a fixed location data unit, and a computer.

17. A method of forming a spin-torque transfer (STT) magnetic tunnel junction (MTJ) memory comprising:
providing a first unitary fixed magnetic layer;
forming a first magnetic barrier layer on the first unitary fixed magnetic layer;
forming a first free magnetic layer, comprising a plurality of free magnetic islands, on the first magnetic barrier layer; and
providing a cap layer overlying the first flee magnetic layer.

18. The method of claim 17, including directly connecting the cap layer to the plurality of free magnetic islands.

19. The method of 17, wherein providing a cap layer comprises providing a cap layer island on each of the plurality of free magnetic islands.

20. The method of 17, including forming a plurality of magnetic barrier islands in the first magnetic barrier layer and providing an electromagnetic isolator material in the first magnetic barrier layer between the plurality of magnetic barrier islands.

21. The method of claim 17, including providing a first anti-ferromagnetic layer adjacent said first unitary fixed magnetic layer on a side of the first unitary fixed magnetic layer opposite said first magnetic barrier layer.

22. The method of claim 21, including providing a connecting layer adjacent said first anti-ferromagnetic layer, electrically connecting a first line to said connecting layer and electrically connecting a second line to said cap layer.

23. The method of claim 17, including providing a second unitary fixed magnetic layer between said cap layer and said first free magnetic layer and providing a second magnetic barrier layer between said second unitary fixed magnetic layer and said first free magnetic layer.

24. The method of claim 23, including directly connecting the second magnetic barrier layer to the first plurality of free magnetic islands on a side of the first plurality of free magnetic islands opposite the first magnetic barrier layer.

25. The method of claim 23, including providing a second anti-ferromagnetic layer between the second unitary fixed magnetic layer and the cap layer.

26. The method of claim 23, including providing at least one additional unitary fixed magnetic layer between the second unitary fixed magnetic layer and the first unitary fixed magnetic layer and providing at least one additional free magnetic layer comprising at least one additional plurality of free magnetic islands.

27. The method of claim 23, including providing a second free magnetic layer comprising a second plurality of free magnetic islands between the second magnetic barrier layer and the first free magnetic layer.

28. The method of claim 27, including providing a third unitary fixed magnetic layer between the first free magnetic layer and the second free magnetic layer, providing a third magnetic barrier layer between the third unitary fixed magnetic layer and the second free magnetic layer and providing a fourth magnetic barrier layer between the third unitary fixed magnetic layer and the first free magnetic layer.

29. The method of claim 17, including integrating the STT-MTJ memory into at least one semiconductor die.

30. The method of claim 17, including integrating the STT-MTJ memory into a device selected from the group consisting of a set top box, a music player, a video player, an entertainment unit, a navigation device, a communications device, a personal digital assistant (PDA), a fixed location data unit, and a computer.

31. A spin-torque transfer (STT) magnetic tunnel junction memory comprising:
a first unitary fixed magnetic layer;
a first magnetic barrier layer means on the first unitary fixed magnetic layer;
a first free magnetic layer means comprising a first plurality of free magnetic islands on the first magnetic barrier layer means; and
a cap layer means overlying the first free magnetic layer means.

32. The STT-MTJ memory of claim 31, wherein said cap layer means is directly connected to said first plurality of free magnetic islands.

33. The STT-MTJ memory of claim 31, wherein said cap layer means comprises a plurality of individual cap layer islands associated said first plurality of free magnetic islands of said first free magnetic layer means.

34. The STT-MTJ memory of claim 31, wherein the first magnetic harrier layer means comprises a first plurality of individual magnetic barrier islands, each one of said first plurality of individual magnetic barrier islands being associated with at east one of said first plurality of free magnetic islands.

35. The STT-MTJ memory of claim 31, wherein said first magnetic barrier layer means comprises a first plurality of individual magnetic barrier islands separated by an electromagnetic isolator material and wherein each of the first plurality of free magnetic islands has a footprint over the first unitary fixed magnetic layer and wherein each one of said first plurality of individual magnetic barrier islands has substantially said footprint and is located between one of the first plurality of free magnetic islands and said first unitary fixed magnetic layer.

36. The STT-MTJ memory of claim 31, including a first anti-ferromagnetic layer adjacent said first unitary fixed magnetic layer on a side of the first unitary fixed magnetic layer opposite said first magnetic barrier layer means.

37. The STT-MTJ memory of claim 31, including a second unitary fixed magnetic layer means between said cap layer means and said first free magnetic layer means and a second magnetic barrier layer means between said second unitary fixed magnetic layer and said first free magnetic layer means.

38. The STT-MTJ memory of claim 37, including at least one additional unitary fixed magnetic layer between said second unitary fixed magnetic layer means and said first unitary fixed magnetic layer and at least one additional free magnetic layer means comprising at least one additional plurality of free magnetic islands.

39. The STT-MTJ memory of claim 37, Wherein said second magnetic barrier layer means is connected to said first plurality of free magnetic islands on a side of said first plurality of free magnetic islands opposite from said first magnetic barrier layer means.

40. The STT-MTJ memory of claim 39, including a second free magnetic layer means comprising a second plurality of free magnetic islands between the second magnetic bather layer means and said first free magnetic layer means.

41. The STT-MTJ of claim 40, including a third unitary fixed magnetic layer between said first free magnetic layer means and said second free magnetic layer means, a third magnetic barrier layer means between said third unitary fixed magnetic layer and said second free magnetic layer means and a fourth magnetic barrier layer means between said third unitary fixed magnetic layer and said first free magnetic layer means.

42. The STT-MTJ memory of claim 31 integrated into at least one semiconductor die.

43. The STT-MTJ memory of claim 31 integrated into a device selected from the group consisting of a set top box, a music player, a video player, an entertainment unit, a navigation device, a communications device, a personal digital assistant (PDA), a fixed location data unit, and a computer.

44. A method of forming a spin-torque transfer (STT) magnetic: tunnel junction memory comprising:
a step for providing a first unitary fixed magnetic layer;
a step for forming a first magnetic barrier layer on the first unitary fixed magnetic layer;
a step for forming a first free magnetic layer, comprising a plurality of free magnetic islands, on the first magnetic barrier layer; and
a step for providing a cap layer overlying the first free magnetic layer.

45. The method of claim 44, including a step or directly connecting the a layer to the first plurality of free magnetic islands.

46. The method of 44, wherein the step for providing a cap layer comprises a step for providing a cap layer island on each of the first plurality of free magnetic islands.

47. The method of 44, including a step for forming a plurality of magnetic barrier islands in the first magnetic barrier layer and providing an electromagnetic isolator material in the first magnetic barrier layer between the plurality of magnetic barrier islands.

48. The method of claim 44, including a step for providing a first anti-ferromagnetic layer adjacent said first unitary fixed magnetic layer on a side of the first unitary fixed magnetic layer opposite said first magnetic barrier layer.

49. The method of claim 44, including a step for providing a connecting layer adjacent said first anti-ferromagnetic layer, electrically connecting a first line to said connecting layer and electrically connecting a second line to said cap layer.

50. The method of claim 44, including a step for providing a second unitary fixed magnetic layer between said cap layer and said first free magnetic layer and a step for providing a second magnetic barrier layer between said second unitary fixed magnetic layer and said first free magnetic layer.

51. The method of claim 50, including a step for providing at least one additional unitary fixed magnetic layer between the second unitary fixed magnetic layer and the first unitary fixed magnetic layer and a step for providing at least one additional free magnetic layer comprising at least one additional plurality of free magnetic islands.

52. The method of claim 50, including a step for directly connecting the second magnetic barrier layer to the first plurality of free magnetic islands on a side of the first plurality of free magnetic islands opposite the first magnetic barrier layer.

53. The method of claim 50, including a step for providing a second anti-ferromagnetic layer between the second unitary fixed magnetic layer and the cap layer.

54. The method of claim 50, including a step for providing a second free magnetic layer comprising a second plurality of free magnetic islands between the second magnetic barrier layer and the first free magnetic layer.

55. The method of claim 54, including a step for providing a third unitary fixed magnetic layer between the first free magnetic layer and the second free magnetic layer, a step for providing a third magnetic barrier layer between the third unitary fixed magnetic layer and the second free magnetic layer and a step for providing a fourth magnetic barrier layer between the third unitary fixed magnetic layer and the first free magnetic layer.

56. The method of claim 44, including a step for integrating the STT-MTJ memory into at least one semiconductor die.

57. The method of claim 44, including a step for integrating the STT-MTJ memory into a device selected from the group consisting of a set top box, a music player, a video player, an entertainment unit, a navigation device, a communications device, a personal digital assistant (PDA), a fixed location data unit, and a computer.
